(19) United States
(12) Patent Application Publication
(10) Pub. No.: US 2026/0040665 A1
(43) Pub. Date: Feb. 5, 2026

(54) INTEGRATED CIRCUIT WITH I/O CPODE DEVICES

(71) Applicant: Taiwan Semiconductor Manufacturing Co., Ltd., Hsinchu (TW)

(72) Inventors: Sung-Hsin YANG, Hsinchu (TW); Chen-Chieh CHIANG, Hsinchu (TW); Jia-Ren CHEN, Hsinchu (TW); Ying Ming WANG, Hsinchu (TW); Yuan Tsung TSAI, Hsinchu (TW)

(21) Appl. No.: 18/794,913

(22) Filed: Aug. 5, 2024

(51) Int. Cl. H01L 27/088; H01L 29/40; H01L 29/78

(52) U.S. Cl. CPC H10D 84/83; H10D 30/608; H10D 30/62; H10D 64/111

(57) ABSTRACT

An integrated circuit includes both core transistors in a core circuitry region and I/O transistors in an I/O circuitry region. A layout of the integrated circuit includes semiconductor fins extending in a first direction and gate structures extending in a second direction. Core CPODE regions are formed between core transistors in a semiconductor fin. I/O CPODE regions are formed between I/O transistors in a semiconductor fin.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an integrated circuit, in accordance with some embodiments.

FIGS. 2A and 2B are top views of a layout of semiconductor fins and sacrificial gate structures, in accordance with some embodiments.

FIGS. 3A and 3B are cross-sectional views of an integrated circuit, in accordance with some embodiments.

FIG. 4 is a cross-sectional view of an integrated circuit, in accordance with some embodiments.

FIGS. 5A and 5B illustrates graphs associated with an integrated circuit, in accordance with some embodiments.

FIGS. 6A-6C are top and cross-sectional views of I/O circuitry of an integrated circuit, in accordance with some embodiments.

FIG. 6D is a cross-sectional view of the integrated circuit 100 at a core circuitry region 102, in accordance with some embodiments.

FIGS. 7A and 7B are top views of an integrated circuit, in accordance with some embodiments.

FIG. 7C includes a graph of signals associated with the integrated circuits of FIGS. 7A and 7B, in accordance with some embodiments.

FIGS. 8A and 8B are cross-sectional views of an integrated circuit, in accordance with some embodiments.

FIGS. 9A and 9B are cross-sectional views of an integrated circuit, in accordance with some embodiments.

FIG. 10 is a cross-sectional view of an integrated circuit, in accordance with some embodiments.

FIG. 11 is a top view of an integrated circuit, in accordance with some embodiments.

FIG. 12 is a top view of an integrated circuit, in accordance with some embodiments.

FIG. 13 is a flow diagram of a method for manufacturing integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure provide an integrated circuit having both core transistors and I/O transistors. The I/O transistors are different from core transistors in that I/O transistors are larger and have a thicker gate oxide than do core transistors so that they can withstand larger voltages. Embodiments of the present disclosure provide an improved layout for the I/O transistors. In particular, embodiments of the present disclosure utilize continuous poly-on-diffusion edge CPODE structures in the layout for I/O transistor regions. The layout of the I/O transistor regions includes a plurality of semiconductor fins extending in a first lateral direction. Trench isolation regions are formed in the fins. The layout of the I/O transistor regions includes a plurality of gate structures extending in a second direction across the fins. The CPODE structures include a gate structure positioned on the trench isolation regions and in contact with the fin on both sides of the trench isolation region. This enables a much denser layout of I/O transistors in the I/O region. The result is that the area consumed by I/O circuitry is greatly reduced. This enables a greater number of circuit structures for a given area, resulting in higher performing integrated circuits.

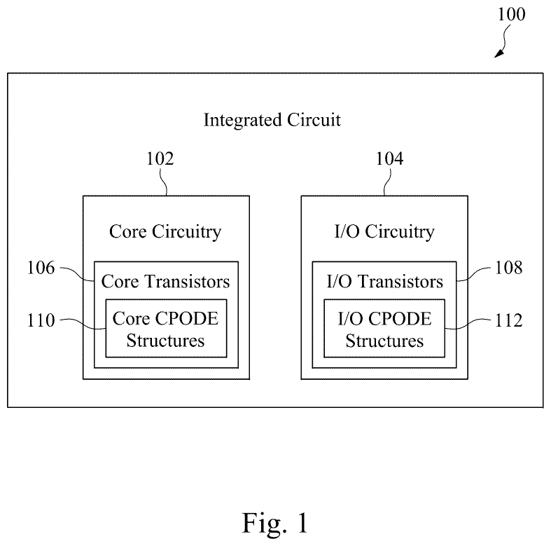

FIG. 1 is a block diagram of an integrated circuit 100, in accordance with some embodiments. The integrated circuit includes core circuitry 102 and I/O circuitry 104. The core circuitry 102 includes core transistors 106. The I/O circuitry 104 includes I/O transistors 108. The core circuitry 102 includes core CPODE structures 110. The I/O circuitry 104 includes I/O CPODE structures 112. As will be set forth in more detail below, the components of the integrated circuit 100 cooperate to enable a higher density of transistors in the integrated circuit 100.

In some embodiments, the core circuitry 102 and the I/O circuitry 104 differ from each other in several ways. The I/O circuitry 104 may deal with signals directly received from sources external to the integrated circuit 100. This can include outputting signals to external sources and receiving signals from external sources. The I/O circuitry 104 may deal with analog signals, unexpected or unsteady voltages, or electrostatic buildup or discharges. The core circuitry 102 may include primarily digital circuitry including complex logic or processing circuitry.

The core circuitry 102 may include vast numbers of circuit structures operating at very high speeds (very high switching frequencies) in complex configurations. In order to promote high frequency operation and to enable larger numbers of devices in a particular area footprint, it is beneficial for the core transistors 106 of the core circuitry 102 to have very small layouts. In order to ensure lower power consumption and reduced risk of damaging the core transistors 106, it is beneficial for the core circuitry 102 to operate at a lower supply voltage than the I/O circuitry. Furthermore, the core transistors 106 may have relatively thin gate dielectric layers.

In contrast, the I/O circuitry 104 may receive relatively high voltage signals or other types of transient signals from external sources. The I/O circuitry 104 may also receive data signals with relatively low voltage amplitudes from the core circuitry 102 and may outputs the data signals to external circuitry at relatively high voltage amplitudes. Accordingly, the I/O circuitry 104 may operate at an I/O supply voltage that is higher than the core supply voltage.

Accordingly, in ensure that the I/O transistors 108 can withstand relatively high voltages, the I/O transistors 108 may have larger features than the core transistors 106. The larger features of the I/O transistors 108 can include gate structures having larger areas than the gate structures of the core transistors 106. The larger features of the I/O transistors 108 can also include thicker gate oxides than the gate oxides of the core transistors 106.

In some embodiments, the core circuitry includes logic cells. The logic cells can include flip-flops and lookup tables. The flip-flops and lookup tables can be implemented in a programmable logic array, such as a field programmable gate array. The flip-flops and logic cells may be implanted with the core transistors 106.

In some embodiments, the core circuitry 102 includes logic gates. The logic gates can include inverters, AND gates, NAND gates, OR gates, NOR gates, XOR gates, XNOR gates, or other types of logic gates. The logic gates are made up of core transistors 106.

In some embodiments, the core circuitry 102 includes memory circuitry. The memory circuitry can include memory cells, row decoders, column decoders, read circuits, write circuits, or other types of memory circuitry. The components of the memory circuitry are made up of core transistors 106. In some embodiments, the memory circuitry may include both core transistors 106 and I/O transistors 108.

In some embodiments, the core circuitry 102 includes one or more processors. The one or more processors can include one or more microprocessors, microcontrollers, or control circuits. The one or more processors can include multicore processors, multithreaded processors, hyperthreading processors, or other types of processors. The processors are made up of core transistors 106.

In some embodiments, the I/O circuitry 104 includes contact pads at a surface of the integrated circuit 100. The contact pads can include substantially flat conductive surfaces configured to receive one or more connecting structures that enable connection to an external circuit. The connection structures can include bonding wires, solder bumps, solder balls, reflow layers, or other types of structures. The contact pads can send and receive data signals, supply voltages, or other types of signals.

In some embodiments, the I/O circuitry includes can include one or more drivers. The drivers are coupled to the contact pads. The drivers may receive data signals from the contact pads with unknown voltage amplitudes and may convert the data signals to a known amplitude, such as an amplitude of the I/O supply voltage. The drivers may also receive data signals from the core circuitry 102 and may drive the data signals to one or more of the contact pads for transmission to an external circuit. The drivers may receive the data signals with amplitudes corresponding to the core supply voltage and output the data signals at amplitudes corresponding to the I/O supply voltage. The drivers are made up of I/O transistors 108.

In some embodiments, the I/O circuitry includes one or more level shifters. The level shifters are coupled between the core circuitry 102 and the drivers of the I/O circuitry 104. The level shifters may shift the data received from the core at the core supply voltage to the I/O supply voltage and output the data to the one or more drivers. The level shifters may receive data from the drivers at the I/O supply voltage and may shift the data to the core supply voltage in order to safely provide the data to the core circuitry 102. The level shifters are made up of I/O transistors 108.

In some embodiments, the I/O circuitry 104 includes electrostatic discharge protection circuitry. It is possible that electrostatic charges may build up at the contact pads or in the vicinity of the integrated circuit 100. Such a buildup of electrostatic charge can result in an electrostatic discharge. Without taking precautionary measures, it is possible that an electrostatic discharge could damage the core transistors 106. The electrostatic discharge protection circuitry protects the core transistors 106 from electrostatic discharges. The electrostatic discharge protection circuitry is made up of I/O transistors 108.

In some embodiments, the I/O circuitry 104 includes an analog-to-digital converter. The analog-to-digital converter may receive analog signals from a source external to the integrated circuit 100 and convert them to digital signals. Alternatively, the analog-to-digital converter may receive analog signals generated within the integrated circuit 100 and convert them to digital signals. The analog-to-digital converter is made up of I/O transistors 108.

In some embodiments, the core transistors 106 and the I/O transistors 108 are FinFET transistors. A basic layout of core transistors 106 at an initial stage of processing includes forming a plurality of semiconductor fins extending in parallel in a first lateral direction. Source/drain and channel regions of the transistors will be formed in the fins, with each channel region extending in the first lateral direction between adjacent source/drain regions. Trench isolation regions are also formed in the fins to electrically isolate adjacent transistors. The layout includes forming a plurality of sacrificial gate regions extending across the fins in a second lateral direction perpendicular to the first lateral direction. The sacrificial gate regions correspond to regions at which gate structures will be deposited to form the gate electrodes of the transistors.

The layout of the I/O transistors 108 includes I/O CPODE structures 112. The I/O CPODE structures 112 correspond to gate structures positioned on the trench isolation regions. More particularly, the CPODE structures 112 include dummy gate regions that overlap both a first edge of the trench isolation region and a second edge of the trench isolation region opposite the first edge in the first direction. This enables transistors on both sides of the trench isolation regions to be positioned closer to each other than would be allowed in the absence of the CPODE structures 112.

Accordingly, utilizing CPODE structures 112 in the I/O circuitry 104 provides a large area savings in the I/O circuitry 104. A larger density of I/O transistors 108 can be formed in the I/O circuitry 104 by utilizing CPODE structures 112.

In some embodiments, the core circuitry 102 includes core CPODE structures 110. The core CPODE structures 110 are similar in some ways to the I/O CPODE structures 112. In practice, the I/O CPODE structures 112 are significantly larger than the core CPODE structures 110. For example, a width of the I/O CPODE structures 112 in the first lateral direction may be between two times and five times as wide as the core CPODE structures 110. Furthermore, after the core transistors 106 and the I/O transistors 108 are complete, the dummy gate structures of the I/O CPODE structures 112 are separated from the trench isolation region by the thick I/O gate dielectric, or as the dummy gate structures of the core CPODE structures 110 are separated from the trench isolation region by the thin core gate dielectric.

Further details regarding the layout of the I/O transistors 108 and the I/O CPODE structures 112 are set forth in relation to subsequent figures.

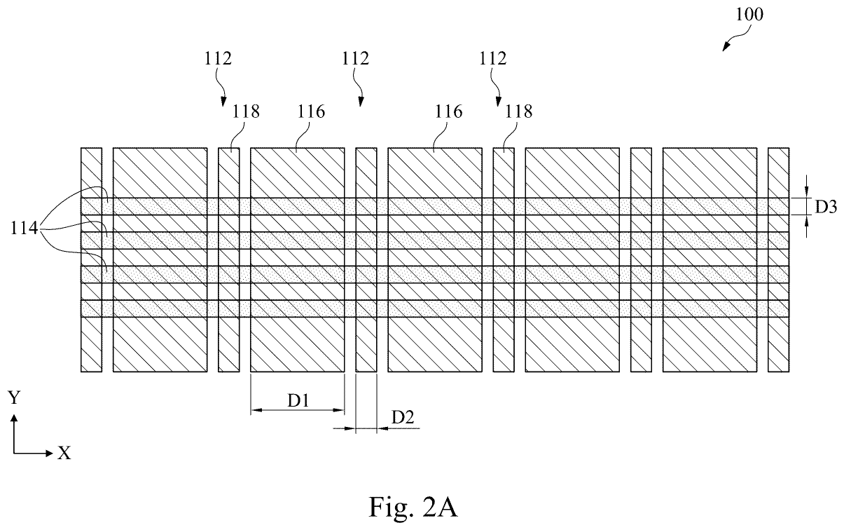

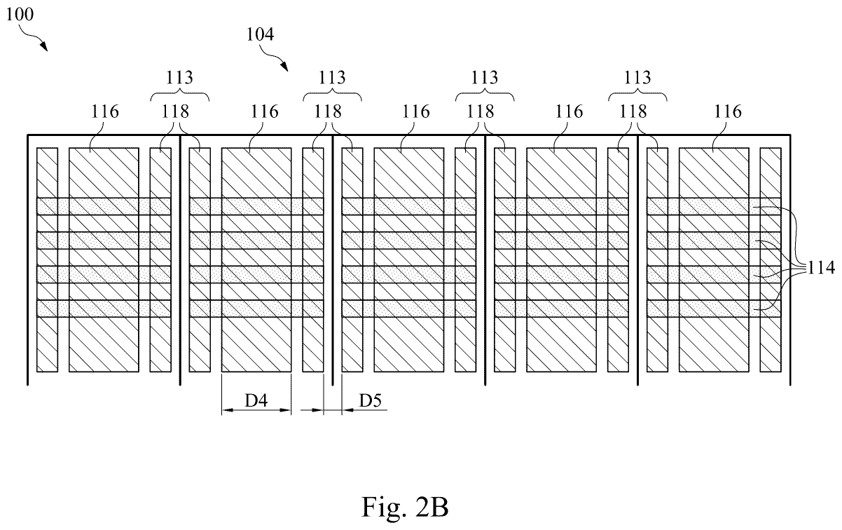

FIG. 2A is a top view layout of an integrated circuit 100, in accordance with some embodiments. The layout of FIG. 2A is one example of a portion of a layout of the I/O circuitry 104 of FIG. 1, in accordance with some embodiments. Furthermore, the layout of FIG. 2A illustrates the locations of some of the I/O transistors 108 that will be formed in the integrated circuit, in accordance with some embodiments.

The layout of FIG. 2A illustrates the positions of a plurality of semiconductor fins 114 extending in the X direction. The layout of FIG. 2A also illustrates the positions of a plurality of gate structures extending in the Y direction substantially perpendicular to the semiconductor fins 114. More particularly, the view of FIG. 2A illustrates the positions of sacrificial gate structures 116 and sacrificial dummy gate structures 118, as will be set forth in more detail below. The simplified layout of FIG. 2A does not illustrate trench isolation regions, source/drain regions, source/drain contacts, gate contacts, or other features. The layout of the semiconductor fins 114 and the sacrificial gate structures 116/118 determines the positions and density of I/O transistors 108 to be formed, in accordance with some embodiments.

Each sacrificial gate structure 116 overlies a plurality of semiconductor fins 114. The location at which a sacrificial gate structure 116 overlies a semiconductor fin 114 corresponds to a potential location of a channel region of a transistor. The reason that the term “potential location” is used, is that the final circuit layout may result in transistors not being formed at some of the locations at which a sacrificial gate structure 116 overlies a semiconductor fin 114. Nevertheless, in the example shown in FIG. 2A, each sacrificial gate structure 116 overlies four semiconductor fins 114 and, thus, for transistors may be formed in accordance with each sacrificial gate structure 116. In practice, a sacrificial gate structure 116 may overlies more or fewer semiconductor fins 114 than shown in FIG. 2A.

Each sacrificial dummy gate structure 118 corresponds to the location of a CPODE structure 112, in accordance with some embodiments. Though not shown in FIG. 2A, trench isolation regions are formed in the semiconductor fins 114 below the sacrificial dummy gate structures 118. Accordingly, each sacrificial dummy gate structure 118 entirely overlies the trench isolation regions. A CPODE structure 112 corresponds to a sacrificial dummy gate structure 118 (or a subsequent gate structure that replaces the sacrificial dummy gate structure 118) entirely covering the portion of a trench isolation structure in each semiconductor fin 114.

In other possible solutions, an I/O circuitry layout can include poly-on-diffusion edge (PODE) structures rather than CPODE structures. The PODE structures call for separate dummy gate structures on each edge of the trench isolation regions. Each of the separate dummy gate structure of the PODE structures is separated from the other by a selected distance based on layout design rules. Furthermore, each dummy gate structure of the PODE structure is separated from an adjacent sacrificial gate structure 116 by the selected distance. The result is a comparatively large area consumption in comparison to the usage of the CPODE structures in accordance with principles of the present disclosure.

In some embodiments, each sacrificial gate structure 116 has a dimension D1 in the X direction. The dimension D1 is between 500 nm and 1500 nm, in some embodiments. The dimension D1 corresponds to the channel length of I/O transistors 108. Other values for the dimension D1 can be utilized without departing from the scope of the present disclosure.

In some embodiments, each sacrificial dummy gate structure 118 has a dimension D2 in the X direction. The dimension D2 can be between 150 nm and 350 nm, in some embodiments. The dimension D2 corresponds to the width of the CPODE structures 112. Other values can be utilized for the dimension D2 without departing from the scope of the present disclosure. The ratio of D1 to D2 is between 1.5 and 10.

Each semiconductor fin 114 has a dimension D3 in the Y direction. The dimension D3 corresponds to the channel width of individual transistors formed from the fins 114. The dimension D3 can be between 50 nm and 500 nm. Other values can be utilized for the dimension D3 without departing from the scope of the present disclosure.

The layout of FIG. 2A also illustrates a dimension D4 corresponding to the distance between adjacent sacrificial gate structures 116 separated by a CPODE structure 112.

In some embodiments, after formation of the semiconductor fins 114 and the trench isolation regions in the semiconductor fins 114, a sacrificial gate material is deposited overlying the semiconductor fins 114. The sacrificial gate material is patterned to form the sacrificial gate structures 116/118 shown in FIG. 2A. The sacrificial gate structures 116/118 are sacrificial in the sense that the material of the sacrificial gate structures 116/118 will be removed and replaced with more highly conductive materials for the gate electrodes of the I/O transistors 108. Further details regarding these materials and structures will be described below in relation to subsequent figures.

FIG. 2B is a top view of a layout of I/O circuitry 104 of an integrated circuit 100, in accordance with some embodiments. The portion of the I/O circuitry 104 shown in the layout of FIG. 2B is substantially similar in many regards to the layout shown in FIG. 2A. In particular, semiconductor fins 114 and sacrificial gate structures 116/118 are present. However, FIG. 2B illustrates PODE structures 113. Each PODE structure 113 includes two sacrificial dummy gate structures 118 each positioned over a portion of a trench isolation region (not shown).

In some embodiments, each sacrificial gate structure 116 of FIG. 2B has a dimension D4 in the X direction. The dimension D5 is between 500 nm and 1000 nm, in some embodiments. Other values for the dimension D5 can be utilized without departing from the scope of the present disclosure.

In some embodiments, each pair of sacrificial dummy gate structures 118 of each PODE structure 113 is separated by a dimension D6. The dimension D6 is between 100 nm and 200 nm, though other distances can be utilized without departing from the scope of the present disclosure. Accordingly, pairs of adjacent sacrificial gate structures 116 separated by a PODE structure 113 are separated by a greater distance than are sacrificial gate structures 116 separated by a CPODE structure 112. The extra distance is the sum of the dimension D6 and the dimension D2, in accordance with some embodiments. Accordingly, utilization of CPODE structures can result in a large reduction in area consumption. In some embodiments, the ratio of D5 to D6 is between 2.5 and 10.

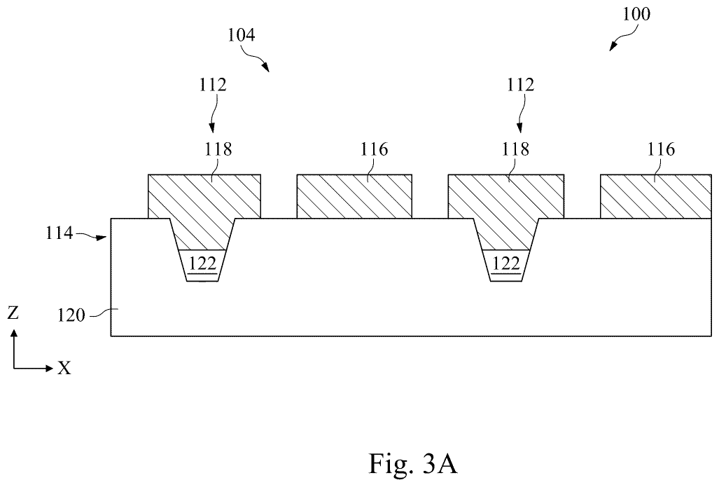

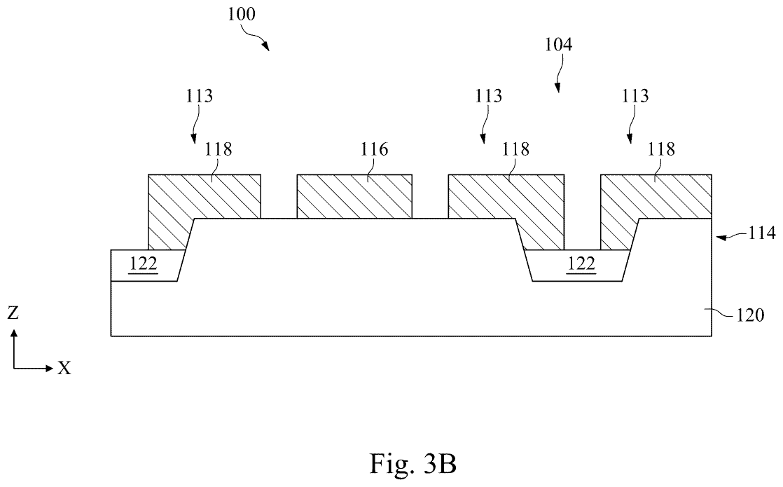

FIG. 3A is a cross-sectional view of the integrated circuit 100, at an intermediate stage of processing, in accordance with some embodiments. The integrated circuit 100 of FIG. 3A can be formed in accordance with the layout shown in FIG. 2A. FIG. 3A illustrates a single semiconductor fin 114 extending in the X direction. FIG. 3A illustrates trench isolation regions 122 formed in the semiconductor fin 114. FIG. 3A illustrates sacrificial gate structures 116 overlying the semiconductor fin 114. FIG. 3A illustrates sacrificial dummy gate structures 118 overlying the semiconductor fin 114. More particularly, the sacrificial dummy gate structures 118 overlie the trench isolation regions 122, thereby defining CPODE structures 112. Details regarding the processes and materials for forming the structures are provided below.

The integrated circuit includes a semiconductor substrate 120. The semiconductor fins 114 are formed by patterning the semiconductor substrate 120 to form trenches in the semiconductor substrate 120, as will be described in further detail below. Accordingly, the semiconductor fins 114 are made from the material of the semiconductor substrate 120, in accordance with some embodiments.

The substrate 120 may be a semiconductor substrate, such as a bulk semiconductor, or the like, which may be doped (e.g., with a p-type or an n-type dopant) or undoped. In an exemplary embodiment, the substrate includes silicon. Alternatively, the substrate 120 can include other semiconductor materials such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Patterning of the substrate 120 to form the fins 114 can be accomplished in the following manner, in accordance with some embodiments. The hard mask material may be formed on the substrate 120. The hard mask material may be patterned in accordance with a photolithography process to form a patterned hard mask. After patterning of the hard mask, trenches have been formed in the substrate 120 by performing an etching process in the presence of the hard mask. The trenches can be formed with an anisotropic etching process that etches in the downward direction. The result of the etching process is that a plurality of semiconductor fins 114 are formed from substrate 120. Said another way, each semiconductor fin 114 protrudes upward from the substrate 120. The semiconductor fins 114 extend in the X direction in accordance with the layout shown in FIG. 2A. After formation of the semiconductor fins 114, doped well regions may be formed in the fins by performing a dopant implantation process. P-well regions may be utilized for N-channel devices. N-well regions may be utilized for P-channel devices.

After formation of the semiconductor fins 114, trench isolation regions 122 have been formed. The trench isolation regions 122 can be formed by forming trenches in the fins 114. A plurality of trenches may be formed in each fin 114. The location of the trenches in a semiconductor fin 114 corresponds to locations between two transistors adjacent to each other in the X direction for which electrical isolation is called for. The etching process may also form further trenches in the substrate 120 between semiconductor fins 114. The etching process can be performed in the presence of the hard mask has been patterned in accordance with a photolithography process substantially similar to the process described above.

After formation of the trenches in the semiconductor fins 114, a dielectric material is deposited on the semiconductor substrate 120 between the semiconductor fins 114 and in the trenches formed in the semiconductor fins 114. The dielectric material may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure.

In some embodiments, after deposition of the dielectric material for the trench isolation regions 122, a chemical mechanical planarization (CMP) process is performed to remove excess material of the shallow trench isolation region 122 from the top surface of the hard mask. An etch-back process is performed to recess the dielectric material with respect to the top surface of the semiconductor fins 114. After the etchback process, the trench isolation regions 122 are formed as shown in FIG. 3A. The top surface of each shallow trench isolation regions 122 is recessed with respect to the top surface of the semiconductor fin 114.

In some embodiments, after formation of the trench isolation regions 122, the sacrificial gate structures 116/118 are formed over the fins 114. The sacrificial dummy gate structures 118 extend in the Y direction, perpendicular to the fins 114. Each sacrificial dummy gate structure 118 crosses multiple fins 114. The sacrificial gate structures 116/118 are also formed in the trenches between fins. The result is that each sacrificial gate structure 116 is in contact with both side surfaces and the top surface of the semiconductor fin 114.

The sacrificial gate structures 116/118 are formed by conformally depositing a sacrificial gate material on the integrated circuit 100. The sacrificial gate material covers the semiconductor fins 114, fills the trenches between the semiconductor fins 114, and fills the trenches in which the trench isolation regions 122 are formed. Accordingly, the sacrificial gate material is in contact with the top surface of the trench isolation regions 122. Alternatively, a thin dielectric layer may be deposited conformally prior to deposition of the sacrificial gate material. In an exemplary embodiment, sacrificial gate material includes polysilicon. However, the sacrificial gate material may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate material may be deposited by physical vapor deposition (PVD), CVD, sputter deposition, or other techniques for depositing the selected material.

After deposition of the sacrificial gate material, a hard mask is formed and patterned on the sacrificial gate material. The pattern of the mask corresponds to the pattern of the sacrificial gate structures 116/118 shown in FIG. 2A. After formation of the mask, the sacrificial gate material is patterned in the presence of the mask. The result is the formation of the sacrificial gate structures 116/118 as shown in FIG. 2A.

Though not shown in FIGS. 2A and 2B, an I/O gate oxide layer may be formed prior to formation of the sacrificial gate structures 116/118. The I/O gate oxide layer can be formed of silicon oxide and can be deposited by CVD, ALD, or PVD. The I/O gate oxide layer is also formed at the core circuitry 102. However, after formation of the I/O gate oxide layer, the I/O gate oxide layer is removed from the core circuitry and replaced by a core gate oxide layer that is thinner than the I/O gate oxide layer.

FIG. 3A illustrates sacrificial gate structures 116 on the top surface of the semiconductor fin 114. FIG. 3A also illustrates sacrificial dummy gate structures 118 on a top surface of the trench isolation regions 122 and filling a remainder of the corresponding trench in the semiconductor fin 114. Each sacrificial dummy gate structure 118 spans the entirety of the trench isolation region in the X direction. Accordingly, a portion of the sacrificial dummy gate structure 118 is on a top surface of the semiconductor fin 114 on a first side of the trench isolation region 122 and on a top surface of the semiconductor fin on a second side of the trench isolation region 122 opposite the first side in the X direction. This corresponds to a CPODE structure 112.

Though not shown in FIG. 3A, gate spacer layers may be formed on sidewalls of the sacrificial gate structures 116/118. When the sacrificial gate structures 116/118 are replaced with gate structures, the gate structures of each gate electrode are bounded by the gate spacer layers.

FIG. 3B is a cross-sectional view of a semiconductor fin 114 of the I/O circuitry 104 at a different location than the view of FIG. 3A, in accordance with some embodiments. A primary difference between the structure of FIG. 3B and the structure of FIG. 3A, is the presence of PODE structures 113 in FIG. 3B, whereas CPODE structures are formed in FIG. 3A. In FIG. 3A, the sacrificial gate structures 116/118 appeared to have a substantially similar width dimension in the X direction. However, in practice, the sacrificial gate structures 116 may be significantly wider than the sacrificial dummy gate structures 118, as shown in FIG. 2A.

The semiconductor fin 114 of FIG. 3B may be a same semiconductor fin 114 as shown in FIG. 3A, but at a different portion of the semiconductor fin 114 of FIG. 3A. Alternatively, the semiconductor fin 114 of FIG. 3B may be a different semiconductor fin 114 than those shown in FIG. 3A.

The PODE structures 113 differ from the CPODE structures 112 and that each PODE structure 113 is positioned on the top surface of the semiconductor fin 114 only on one side of each trench isolation region 122. Said another way, a first vertical edge of the sacrificial dummy gate structure 118 is positioned directly over the semiconductor fin 114 on a first side of a trench isolation region 122. A second vertical edge of the sacrificial dummy gate structure 118 opposite the first vertical edge in the X direction is positioned directly over the trench isolation region 122. Each trench isolation region 122 is overlapped by two sacrificial dummy gate structures 118. Each sacrificial dummy gate structure 118 may correspond to a single PODE structure 113. Alternatively, each pair of sacrificial dummy gate structures 118 that overlap a trench isolation region 122 may correspond collectively to a single PODE structure 113. As is apparent from the views of FIGS. 3A and 3B, the distance between adjacent sacrificial gate structures 116 separated by a trench isolation region 122 will be greater when PODE structures 113 are utilized than when CPODE structures 112 are utilized.

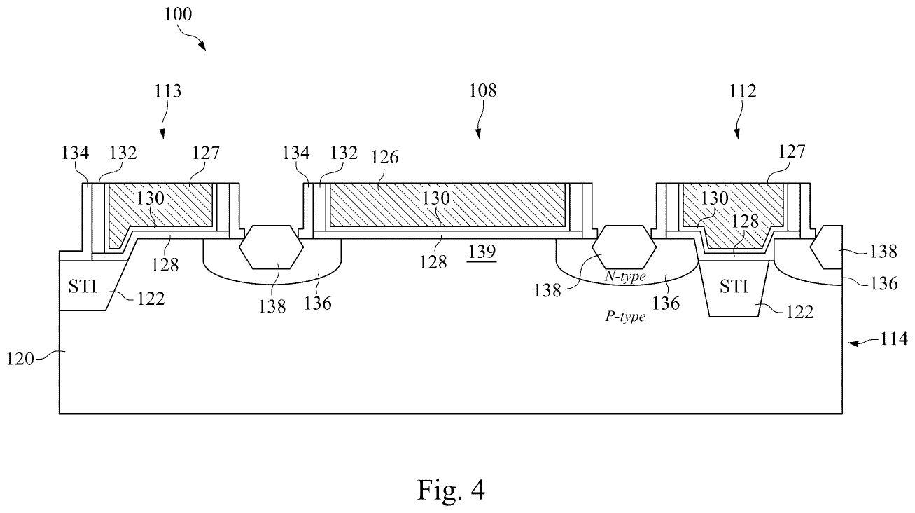

FIG. 4 is a cross-sectional view of an integrated circuit 100, in accordance with some embodiments. The view of FIG. 4 corresponds to a view in which processing of the I/O transistors 108 is substantially complete. The view of FIG. 4 illustrates a location of a semiconductor fin 114 in which an I/O transistor 108 has been formed, a CPODE structure 112 has been formed, and a PODE structure 113 has been formed.

After the stage of processing shown in FIGS. 3A/3B, a gate spacer layer 132 has been formed on sidewalls of the sacrificial gate structures 116/118. The gate spacer layer 132 can include one or more of SiO, SiN, SiON, SiCN, SiOCN, SiOC, or other suitable dielectric materials. The gate spacer layer 132 can be formed by PVD, CVD, ALD, or other suitable deposition processes.

After formation of the gate spacer layers 132, lightly doped source/drain regions 136 are formed. The lightly doped source/drain regions 136 are formed by performing an ion implantation process. In some embodiments, the ion implantation process is performed prior to formation of the gate spacer layer 132. In the example of N-channel transistors, the lightly doped source/drain regions are doped with N-type dopants in the P well region of the semiconductor fin 114. FIG. 4 illustrates an N channel I/O transistor 108. In the example of P-channel transistors, the lightly doped source/drain regions are doped with P-type dopants in an N-well region of a semiconductor fin 114.

In some embodiments, the sacrificial gate structures 116/118 and the gate spacer layer 132 are utilized as a mask for forming source/drain trenches in some embodiments, a dielectric layer 134 is deposited on the gate spacer layer 132 and patterned. The dielectric layer 134 can include one or more of SiO, SiN, SiON, SiCN, SiOCN, SiOC, or other suitable dielectric materials. The dielectric layer 134 may correspond to a contact etch stop layer (CESL).

In some embodiments, after formation and patterning of the dielectric layer 134, source/drain trenches are formed in the lightly doped source/drain regions 136 utilizing the dielectric layers 132/134 and the sacrificial gate structures 116/118 as a mask. In particular, one or more etching processes are performed to form the source/drain trenches in the fins 114. Forming the source/drain trenches includes etching through the semiconductor fins 114. The etching processes can include reactive ion etching (RIE), neutral beam etching (NBE), atomic layer etching (ALE), or the like.

In some embodiments, source/drain regions 138 have been formed in the source/drain trenches. In the illustrated embodiment, the source/drain regions 138 are epitaxially grown from semiconductor material of the fins 114. The source/drain regions 138 fill the source/drain trenches. For each I/O transistor 108, there are two source/drain regions 138. The channel region 139 corresponds to the portion of the semiconductor fin 114 between the source/drain regions 138 separated from the gate structures by the gate oxide.

The source/drain regions 138 may include any acceptable material, such as appropriate for N-type or P-type devices. For N-type devices, the source/drain regions 138 include materials exerting a tensile strain in the channel regions, such as silicon, SiC, SiCP, SiP, or the like, in some embodiments. When P-type devices are formed, the source/drain regions 138 include materials exerting a compressive strain in the channel regions, such as SiGe, SiGeB, Ge, GeSn, or the like, in accordance with certain embodiments. The source/drain regions 138 may have surfaces raised from respective surfaces of the fins and may have facets.

The source/drain regions 138 may be implanted with dopants followed by an annealing process. The source/drain regions 138 may have an impurity concentration of between about 10¹⁹ cm⁻³ and about 10²¹ cm⁻³. N-type and/or P-type impurities for source/drain regions 138 may be any of the impurities previously discussed. In some embodiments, the source/drain regions 138 are in situ doped during growth. The source/drain regions 138 may be doped in-situ during the epitaxial growth process.

In FIG. 4, the sacrificial gate structures 116/118 have been removed from between the gate spacer layers 132. In some embodiments, the sacrificial gate structures 116/118 are removed by an anisotropic dry etch process. For example, the etching process may include a dry etch process using reaction gases that selectively etch the sacrificial gate structures 116/118 without etching the spacer layer 132.

In FIG. 4, and I/O gate oxide layer 128 has been formed. As described previously, the I/O gate oxide layer 128 may be formed prior to formation of the sacrificial gate structures 116/118. The I/O gate oxide layer 128 can include silicon oxide or other suitable dielectric materials. The I/O gate oxide layer 128 can have a thickness between 20 nm and 80 nm. The I/O gate oxide layer can be formed by CVD, PVD, or ALD. Other thicknesses of the I/O gate oxide layer can be utilized without departing from the scope of the present disclosure.

The core circuitry 102, including the core transistors 106 and the core CPODE structures 110 are formed substantially simultaneously in the same process steps using the same materials. One exception is that after formation of the I/O gate oxide layer 128 at both the I/O circuitry 104 and the core circuitry 102, the I/O gate oxide layer 128 is removed at the core circuitry 102. A core gate oxide layer 129 is then formed at the core circuitry 102 prior to formation of the sacrificial gate structures 116/118. The core gate oxide layer 129 can have a same material as the I/O gate oxide layer 128. The core gate oxide layer is thinner than I/O gate oxide layer 128. In some embodiments, the core gate oxide layer has a thickness between 2 nm and 10 nm. Other thicknesses of the core gate oxide layer can be utilized without departing from the scope of the present disclosure. In some embodiments, a ratio between the I/O gate oxide thickness and the core gate oxide thickness is between 40 and 2, though other ratios can be utilized without departing from the scope of the present disclosure.

Returning to FIG. 4, after removal of the sacrificial gate structures 116/118, a high-K gate dielectric layer 130 has been formed. The high-K gate dielectric layer 130 is deposited in a conformal deposition process. The conformal deposition process deposits the high-K gate dielectric layer 130 on the I/O gate oxide layer 128 (or the core oxide layer at the core circuitry 132) and on the gate spacer layers 132. The high-K gate dielectric layer 130 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 130 may be formed by CVD, ALD, or any suitable method. Other thicknesses, deposition processes, and materials can be utilized for the high-K gate dielectric layer 130 without departing from the scope of the present disclosure. The high-K gate dielectric layer 130 is a gate dielectric layer.

In some embodiments, after formation of the high K gate dielectric layer 130, a gate structure 126 is formed in place of the sacrificial gate structures 116. A dummy gate structure 127 is formed in place of the sacrificial dummy gate structures 118. More particularly, the gate structure 126 is formed in place of the sacrificial gate structures 116 and corresponds to gate electrodes of the I/O transistors 108. The gate structure 127 is formed in the same process as the gate structure 126, but in place of the sacrificial dummy gate structures 118 at the CPODE structures 112 and the PODE structures 113. In the final forms, CPODE structures 112 and the PODE structures 113 include the dummy gate structures 127.

The gate structure 126/127 is deposited on all exposed surfaces of the high-K gate dielectric layer 130. Though not apparent in FIG. 4, the gate structure 126 is formed on side surfaces of the semiconductor fin 114 such that the channel region 139 is surrounded by the gate structure 126 on three sides. Although the gate structure 126/127 is shown as a single layer in FIGS. 4, in practice, the gate structure 126/127 can include one or more conductive liner layers, work function layers, glue layers, and gate fill layers that collectively make up the gate structure 126/127. The gate structure 126127 can include one or more of Ti, TiN, Ta, TaN, Al, Cu, Co, Ru, W, Au, or other suitable conductive materials. The gate structure 126/127 can be deposited by PVD, ALD, or CVD. Other configurations, materials, and deposition processes can be utilized for the gate structure 126/127 without departing from the scope of the present disclosure.

At the stage of processing shown in FIG. 4, the I/O transistors 108 and the core transistors 106 are substantially complete, apart from formation of source/drain contacts. As described previously, the I/O transistors 108 and the core transistors 106 are formed substantially simultaneously in the same process steps. The core circuitry 102 includes core CPODE structures 110 and core PODE structures (not shown).

Though not shown in FIG. 4, in further processing steps, cut-gate processes may be performed to electrically isolate portions of the gate structure 126 to form electrically isolated gate electrodes for the transistors that are adjacent to each other in the Y direction.

Though not shown in FIG. 4, source/drain contacts may also be formed. A CESL layer may be formed on the top surface of the source/drain regions 138. An interlevel dielectric layer may then be formed on the CESL layer. Trenches can be formed in the interlevel dielectric layer and the CESL layer to expose the top surfaces of the source/drain regions 138. A silicide may be formed on the exposed portions of the source/drain regions 138. A conductive via or plug, corresponding to a source/drain contact, can be formed in contact with the silicide. Voltages can be applied to source/drain regions 138, or currents can be passed via the source/drain contacts. Gate contacts can also be formed on the gate structures 126/127.

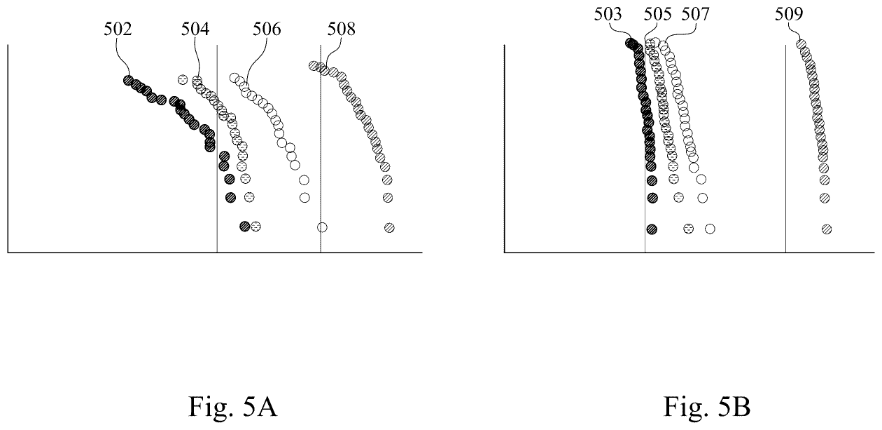

FIG. 5A illustrates graphs 502, 504, 506, and 508 associated with gate induced leakage currents (GIDL) for random telegraph signal (RTS) type fluctuations (noise) in the I/O transistor 108 of FIG. 4 for the PODE structure 113 and the CPODE structure 112. The graph 502 corresponds to GIDL between the I/O transistor 108 and the CPODE structure 112 of FIG. 4 for a situation in which the gate structure 127 of the CPODE structure 112 is biased with a nonzero bias voltage (e.g., 1V). The y-axis corresponds to the 1−CDF % in the x-axis corresponds to leakage current. The graph 504 corresponds to CPODE leakage current when the gate structure 127 is floating. The graph 506 corresponds to PODE leakage current when the gate structure 127 is floating. The graph 508 corresponds to PODE leakage current when the gate structure 127 is at 0 V. As can be seen, biasing the gate structure 127 of the CPODE structure 112 results in the lowest gate induced drain leakage currents. Leaving the gate structure 127 of the CPODE structure 112 floating results of the second lowest gate induced drain leakage currents. Leaving the gate structure 127 of the PODE structure 113 floating results in the third lowest gate induced drain leakage current. Applying ground voltage to the gate structure 127 of the CPODE structure 112 results in the highest gate induced drain leakage currents. Accordingly, in some embodiments, the gate structures 127 are biased to reduce leakage currents. In some embodiments, the gate structures 127 are left floating to reduce leakage currents.

FIG. 5B is a GIDL plot associated with the structures of FIG. 4 in DC conditions, in accordance with some embodiments. The graphs 503, 505, 507, 509 correspond to the structures and conditions of the graphs 502, 504, 506, and 508, respectively. Again, positively biasing the gate structure 127 or leaving the gate structure 127 floating results in the lowest leakage currents.

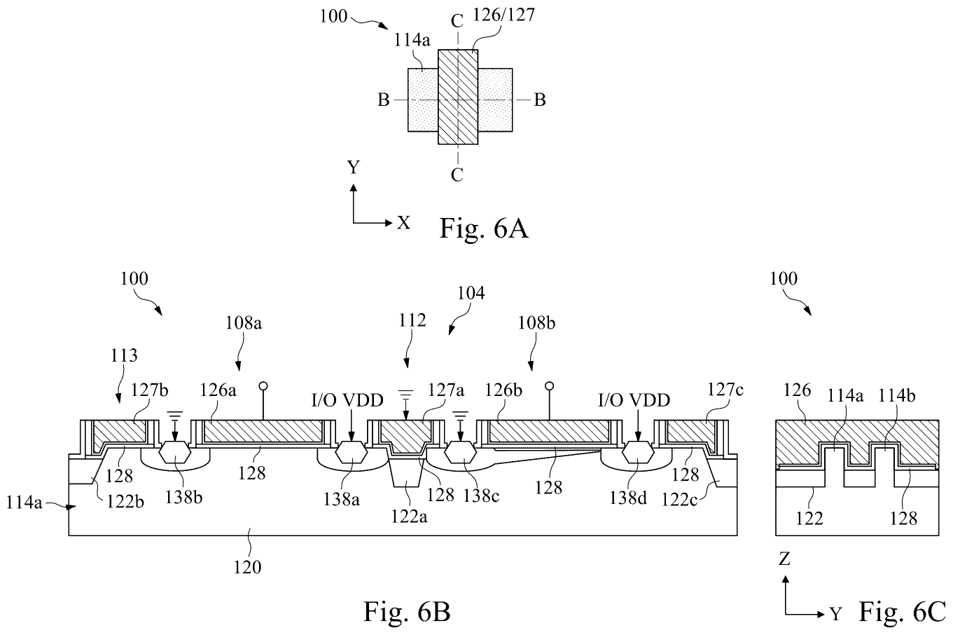

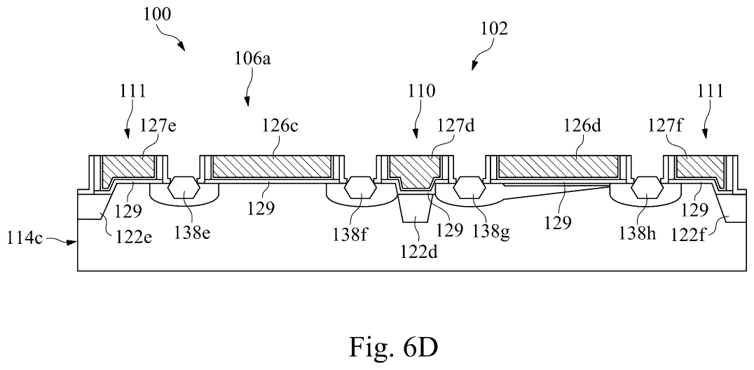

FIG. 6A is a top view of a gate structure 126/127 line across the semiconductor fin 114, in accordance with some embodiments. FIG. 6B is a cross-sectional view of the integrated circuit 100 of FIG. 6A taken along cut lines B of FIG. 6A (though showing multiple gate structure structures 126/127), or, in accordance with some embodiments. FIG. 6C is a cross-sectional view of the integrated circuit 100 of FIG. 6A taken along cut lines C of FIG. 6A (though showing multiple fins 114), in accordance with some embodiments.

FIG. 6B illustrates two I/O transistors 108a/108b separated from each other by a CPODE structure 112. PODE structures 113 are positioned on the far sides of the transistors 108a and 108b. FIG. 6B also illustrates the voltages applied to the source/drain regions 138 and the gate structures 126/127. The transistor 108a has 0 V applied to the source/drain region 138b adjacent to PODE structure 113. The transistor 108a includes VDD applied to the source/drain region 138a adjacent to the CPODE structure 112. The transistor 108a is off (i.e., gate structure 126 receives 0 V for NMOS or VDD for PMOS). The gate structures 127 of the PODE structures 113 are floating. The gate structure 127a of the CPODE structures 112 is grounded. The transistor 108b includes 0 V applied to the source/drain region 138c adjacent to the CPODE structure 112. The transistor 108b includes VDD applied to the source/drain region 138d adjacent to the PODE structure 113. The transistor 108b is on (VDD applied to gate structure 126 for NMOS, 0 V for PMOS). Please refer to the graph of FIG. 5A for leakage currents associated with this structure.

FIG. 6C illustrates that the gate structure 126 of the transistor 108b overlies multiple semiconductor fins 114a/b.

FIG. 6D is a cross-sectional view of the integrated circuit 100 at a core circuitry region 102, in accordance with some embodiments. FIG. 6D illustrates a semiconductor fin 114c including two core transistors 106a/106b separated from each other by a core CPODE structure 110. Core PODE structures 111 are positioned on the far sides of the transistors 106a and 106b. The transistor 106a includes the source/drain region 138e adjacent to PODE structure 111. The transistor 106a includes a source/drain region 138f adjacent to the CPODE structure 110. The transistor 106a includes a gate structure 126c. The CPODE structure 110 includes a dummy gate structure 127d. Accordingly, in FIG. 6D illustrates that the core circuitry 102 and core transistors 106 have substantially similar structures to the I/O circuitry 104 and the I/O transistors 108, though with a core gate oxide 129 and smaller overall dimensions. In some embodiments, the width in the X direction of the gate structures 126 of the core transistors 106 are less than or equal to half the width of the gate structures 126 of the I/O transistors 108.

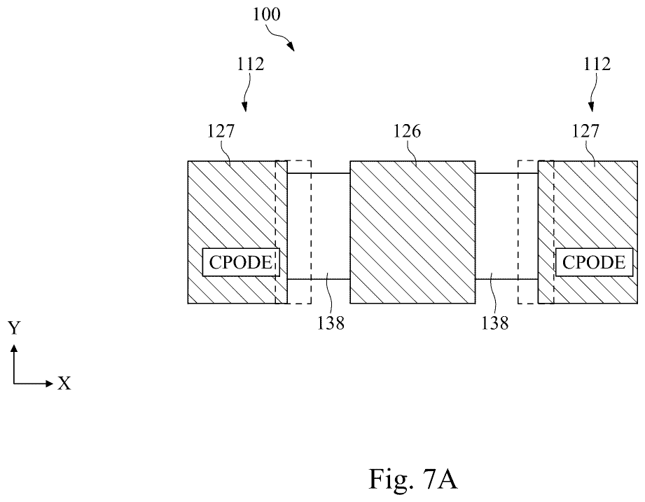

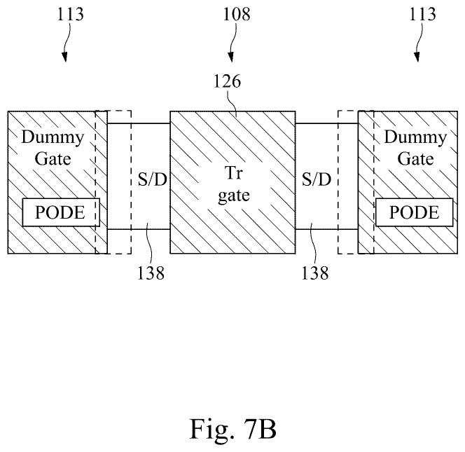

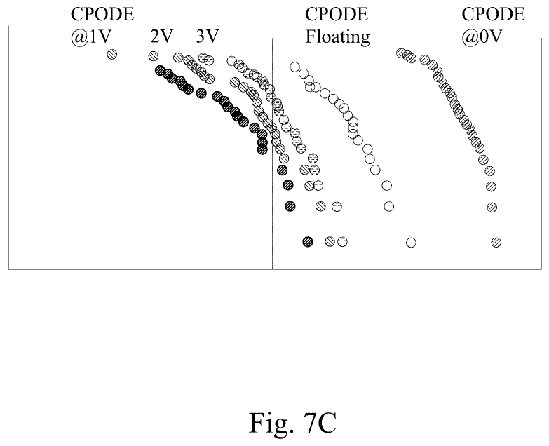

FIG. 7A is a simplified top view of an I/O transistor 108 between two CPODE structures 112, in accordance with some embodiments. FIG. 7B is a simplified top view of an I/O transistor 108 between two PODE structures 113, in accordance with some embodiments. FIG. 7C is a graph illustrating 1−CDF (%) first leakage currents for the CPODE structures 112 of FIG. 7A at various bias voltages and for the PODE structures 113 of FIG. 7B in a floating state, in accordance with some embodiments. Biasing the CPODE structures at one volt provides the lowest leakage currents.

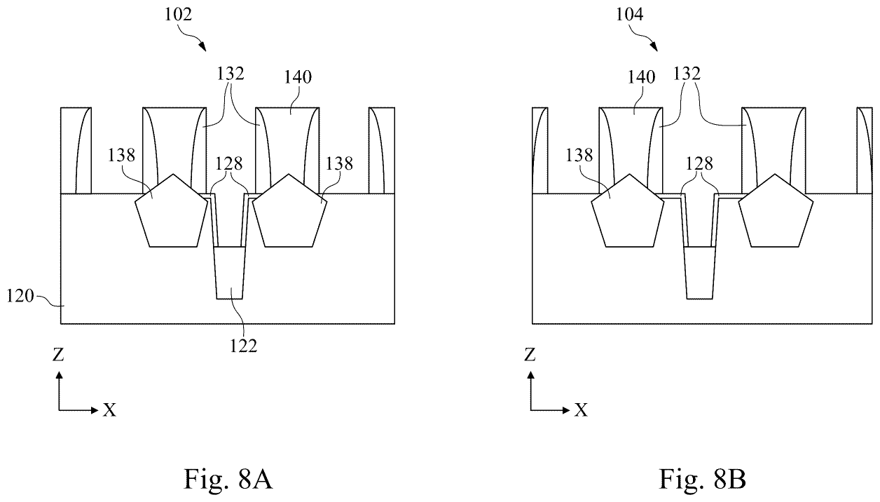

FIG. 8A is a cross-sectional view of core circuitry 102, in accordance with some embodiments. FIG. 8B is a cross-sectional view of I/O circuitry 104 in a same stage of processing as FIG. 8A, in accordance with some embodiments. In FIGS. 8A and 8B, the I/O gate oxide 128 has been performed at both the core circuitry region and the I/O circuitry region. FIGS. 8A and 8B also illustrates source/drain contacts and source/drain regions 138. However, in practice, the structures may not be formed yet at the time that the I/O gate oxide 128 is formed.

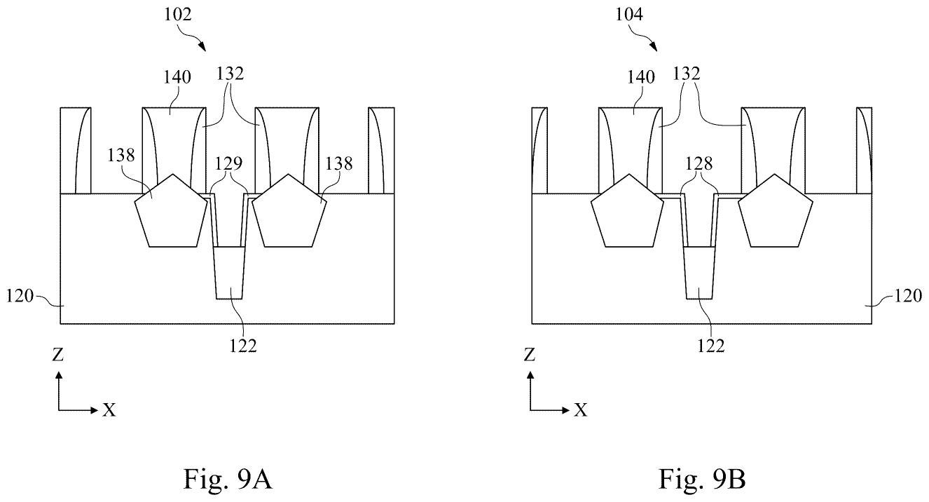

FIG. 9A is a cross-sectional view of core circuitry 102, in accordance with some embodiments. FIG. 9B is a cross-sectional view of I/O circuitry 104 in a same stage of processing as FIG. 9A, in accordance with some embodiments. In FIGS. 9A and 9B, the I/O gate oxide 128 has been removed at the core circuitry region and a core gate oxide 129 is formed in place of the I/O gate oxide 128 at the core circuitry region. The I/O gate oxide 128 remains at the I/O circuitry 104. After formation of the core gate oxide 129, subsequent processing steps including formation of the sacrificial gate structures 116/118, formation of the source/drain regions 138, removal of the sacrificial gate structures 116/118, and formation of the gate structures 126/127 are performed in order to complete formation of the core transistors 106 of the core circuitry region and the I/O transistors 108 of the I/O circuitry region.

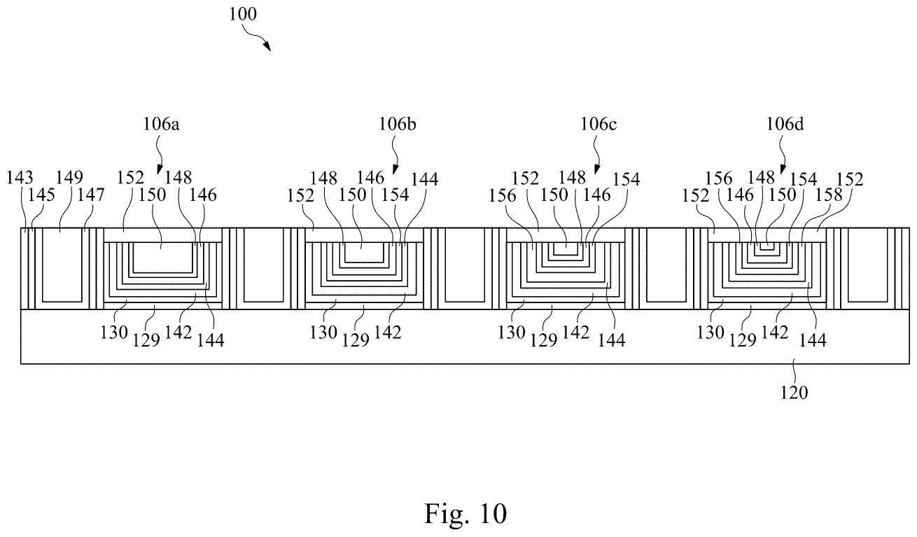

FIG. 10 is a cross-sectional view of an integrated circuit 100, in accordance with some embodiments. The integrated circuit 100 illustrates a low-voltage N-type core transistor 106a, a standard voltage N-type core transistor 106b, a low-voltage P-type core transistor 106d, a standard voltage N-type core transistor 106c, in accordance with some embodiments. As described previously, the gate structure 126 can include a plurality of gate structures, as illustrated in FIG. 10.

Each of the transistors 106a-d includes a dielectric cap layer 152 of silicon nitride above the gate structures including the core gate oxide layer 129, the high K gate dielectric layer 130, a gate structure layer 142, a gate structure layer 144, a gate structure layer 146, a gate structure layer 148, and the gate structure layer 150 corresponding to a gate fill material. In some embodiments, the transistors 106b-d each include a gate structure layer 154. In some embodiments, the transistors 106c and 106d each include a gate structure layer 156. In some embodiments, the transistor 106d includes a gate structure layer 158.

In some embodiments, the gate structure layer 142 is a capping layer including TiN, though other materials can be used without departing from the scope of the present disclosure. In some embodiments, the gate structure layer 144 is a barrier metal including tantalum nitride, though other materials can be utilized without departing from the scope of the present disclosure. In some embodiments, the gate structure 146 is a work function metal including TiAl, though other materials can be utilized without departing from the scope of the present disclosure. In some embodiments, the gate structure layer 148 is a glue layer including titanium nitride, though other materials can be utilized without departing from the scope of the present disclosure. In some embodiments, the gate structure layer 150 is a gate fill material including tungsten, though other materials can be utilized without departing from the scope of the present disclosure. In some embodiments, the gate structure layer 154 is a work function metal including titanium nitride, though other materials can be utilized without departing from the scope of the present disclosure. In some embodiments, the gate structure layer 156 is a work function metal including titanium nitride, though other materials can be utilized without departing from the scope of the present disclosure. In some embodiments, the gate structure layer 158 is a gate structure layer including titanium nitride, though other materials can be utilized without departing from the scope of the present disclosure. Other materials, layers, and combinations of layers can be utilized for the gate structures without departing from the scope of the present disclosure.

In some embodiments, the transistor 106b is an I/O transistor with an I/O gate oxide 128, rather than a core gate oxide 129. In some embodiments, the transistor 106c is a P-type I/O transistor with an I/O gate oxide 128, rather than a core gate oxide 129.

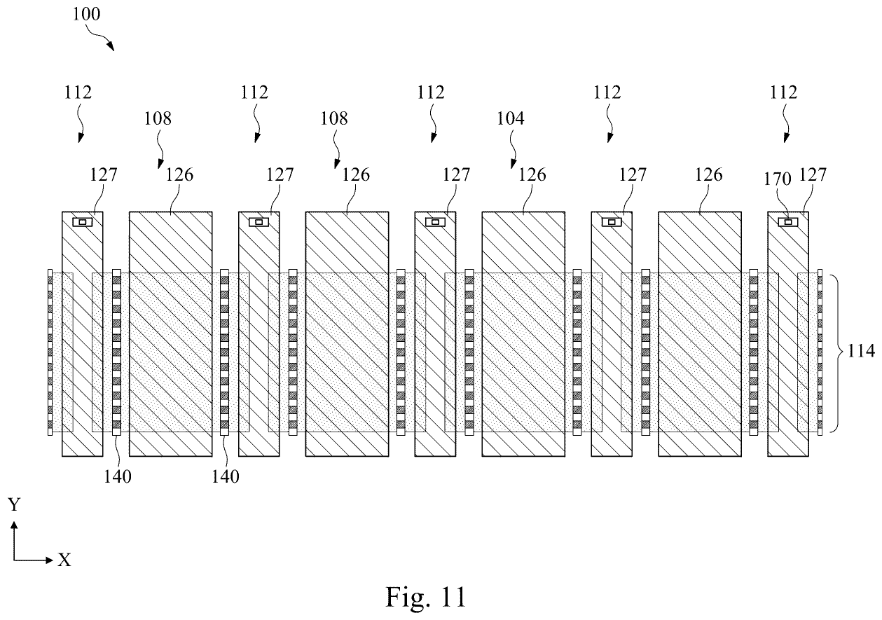

FIG. 11 is a top view layout of I/O circuitry 104 of an integrated circuit 100, in accordance with some embodiments. The layout of FIG. 11 is at a further stage of processing than the layout of FIG. 2A. In the view of FIG. 11, the sacrificial gate structures 116/118 have been replaced with gate structures 126/127. Source/drain contacts 140 have been formed in contact with source/drain regions 138 (not shown). Gate contacts 170 have been formed. CPODE structures 112 have been formed including gate contacts 170 by which voltages can be applied to the gate structures 127 of the CPODE structures 112. A core circuitry 102 may have substantially similar layouts, though with significantly smaller dimensions, in accordance with some embodiments.

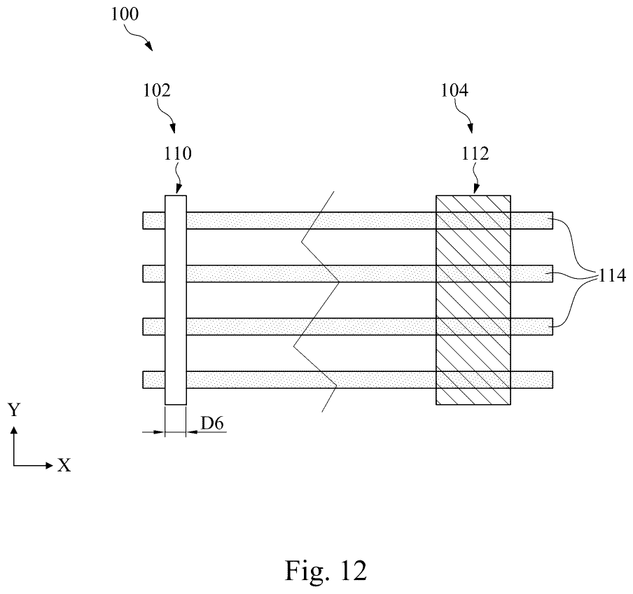

FIG. 12 is a top view layout of an integrated circuit 100, in accordance with some embodiments. FIG. 12 illustrates core circuitry 102 and I/O circuitry 104. More particularly, FIG. 12 illustrates a core CPODE structure 110 in the core circuitry 102 and an I/O CPODE structure 112 in the I/O circuitry 104. The core CPODE structure 110 has a dimension D6 in the X direction. The dimension D7 is between 50 nm and 100 nm, though other dimensions can be utilized without departing from the scope of the present disclosure.

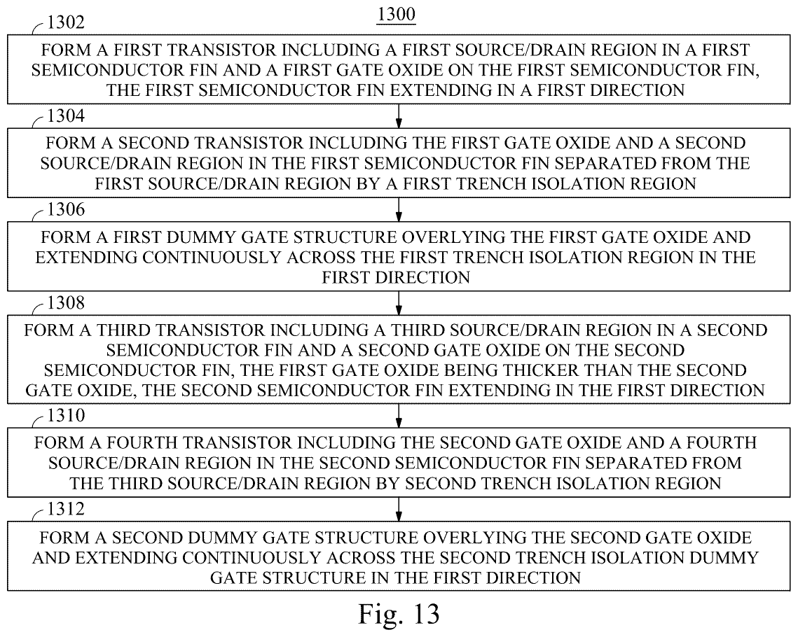

FIG. 13 is a flow diagram of a method 1300 for forming an integrated circuit, in accordance with some embodiments. The method 1300 can utilize the structures, processes, and systems described in relation to FIGS. 1-12. At 1302, the method 1300 includes forming a first transistor including a first source/drain region in a first semiconductor fin and a first gate oxide on the first semiconductor fin, the first semiconductor fin extending in a first direction. One example of a first transistor is the transistor 108a of FIG. 6B. One example of a first semiconductor fin is the semiconductor fin 114a. One example of a first source/drain region is the source/drain region 138a of FIG. 6B. One example of a first gate oxide is the gate oxide 128 of FIG. 6B. At 1304, the method 1300 includes forming a second transistor including the first gate oxide and a second source/drain region in the first semiconductor fin separated from the first source/drain region by a first trench isolation region. One example of a second transistor is the transistor 108b of FIG. 6B. One example of a second source/drain region is the source/drain region 138c of FIG. 6B. One example of a first trench isolation region is the trench isolation region 122a of FIG. 6B. At 1306, the method 1300 includes forming a first dummy gate structure overlying the first gate oxide and extending continuously across the first trench isolation region in the first direction. One example of a first dummy gate structure is the dummy gate structure 127a of FIG. 6B. At 1308, the method 1300 includes forming a third transistor including a third source/drain region in a second semiconductor fin and a second gate oxide on the second semiconductor fin, the first gate oxide being thicker than the second gate oxide, the second semiconductor fin extending in the first direction. One example of a third transistor is the transistor 106a of FIG. 6D. One example of a second semiconductor fin is the semiconductor fin 114c of FIG. 6D. One example of a third source/drain region is the source/drain region 138f of FIG. 6D. One example of a second gate oxide is the gate oxide 129 of FIG. 6D. At 1310, the method 1300 includes forming a fourth transistor including the second gate oxide and a fourth source/drain region in the second semiconductor fin separated from the third source/drain region by a second trench isolation region. One example of fourth transistor is the transistor 106b of FIG. 6D. One example of a fourth source/drain region is the source/drain region 138g of FIG. 6D. One example of a second trench isolation region is the trench isolation region 122d of FIG. 6D. At 1312, the method 1300 includes forming a second dummy gate structure overlying the second gate oxide and extending continuously across the second trench isolation region in the first direction. One example of a second dummy gate structure is the dummy gate structure 127d of FIG. 6D.

Embodiments of the disclosure provide an integrated circuit having both core transistors and I/O transistors. The I/O transistors are different from core transistors in that I/O transistors are larger and have a thicker gate oxide than do core transistors so that they can withstand larger voltages. Embodiments of the present disclosure provide an improved layout for the I/O transistors. In particular, embodiments of the present disclosure utilize continuous poly-on-diffusion edge CPODE structures in the layout for I/O transistor regions. The layout of the I/O transistor regions includes a plurality of semiconductor fins extending in a first lateral direction. Shallow trench isolation regions are formed in the fins. The layout of the I/O transistor regions includes a plurality of gate structures extending in a second direction across the fins. The CPODE structures include a gate structure positioned on the trench isolation regions and in contact with the fin on both sides of the trench isolation region. This enables a much denser layout of I/O transistors in the I/O region. The result is that the area consumed by I/O circuits is greatly reduced. This enables a greater number of circuit structures in either the core region or the I/O region.

In some embodiments, a device includes a first semiconductor fin extending in a first direction, a first transistor of a first type including a first source/drain region in the first semiconductor fin, and a second transistor of the first type including a second source/drain region in the first semiconductor fin. The device includes a first trench isolation region between the first source/drain region and the second source/drain region and a first dummy gate structure extending continuously in the first direction from a first portion of a top surface of the first semiconductor fin adjacent to the first source/drain region across the first trench isolation region to a second portion of the top surface of the first semiconductor fin adjacent to the second source/drain region.

In some embodiments, a method includes forming a first transistor including a first source/drain region in a first semiconductor fin and a first gate oxide on the first semiconductor fin, the first semiconductor fin extending in a first direction and forming a second transistor including the first gate oxide and a second source/drain region in the first semiconductor fin separated from the first source/drain region by a first trench isolation region. The method includes forming a first dummy gate structure overlying the first gate oxide and extending continuously across the first trench isolation region in the first direction and forming a third transistor including a third source/drain region in a second semiconductor fin and a second gate oxide on the second semiconductor fin. The first gate oxide is thicker than the second gate oxide, the second semiconductor fin extending in the first direction. The method includes forming a fourth transistor including the second gate oxide and a fourth source/drain region in the second semiconductor fin separated from the third source/drain region by a second trench isolation region and forming a second dummy gate structure overlying the second gate oxide and extending continuously across the second trench isolation region in the first direction.

In some embodiments, a device includes I/O circuitry including a first transistor of a first type, a second transistor of the first type, and an I/O CPODE structure between the first transistor of the first type and the second transistor of the first type. The device includes core circuitry including a first transistor of a second type, a second transistor of the second type, and a core CPODE structure between the first transistor of the second type and the second transistor of the second type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a first semiconductor fin extending in a first direction;
a first of a first type transistor including a first source/drain region in the first semiconductor fin;
a second of the first type transistor including a second source/drain region in the first semiconductor fin;
a first trench isolation region between the first source/drain region and the second source/drain region; and
a first dummy gate structure extending continuously in the first direction from a first portion of a top surface of the first semiconductor fin adjacent to the first source/drain region across the first trench isolation region to a second portion of the top surface of the first semiconductor fin adjacent to the second source/drain region.

2. The device of claim 1, comprising:
a second semiconductor fin;
a first of a second type transistor including a third source/drain region in the second semiconductor fin;
a second of the second type transistor including a fourth source/drain region in the second semiconductor fin;
a second trench isolation region between the third source/drain region and the fourth source/drain region; and
a second dummy gate structure extending continuously in the first direction from a first portion of a top surface of the second semiconductor fin adjacent to the third source/drain region across the second trench isolation region to a second portion of the top surface of the second semiconductor fin adjacent to the fourth source/drain region.

3. The device of claim 2, wherein the first transistor of the first type and the second transistor of the first type include an I/O gate oxide having a first thickness, wherein the first transistor of the second type and the second transistor of the second type include a core gate oxide having a second thickness, wherein a ratio of the first thickness to the second thickness is between 1.5 and 10.

4. The device of claim 2, wherein the first dummy gate structure has a width in the first direction that is at least double a width of the second dummy gate structure in the first direction.

5. The device of claim 2, wherein the first transistor of the first type has a first gate structure having a first width in the first direction, wherein the first transistor of the second type has a second gate structure having a second width in the first direction, wherein the first width is at least double the second width.

6. The device of claim 2, comprising:
I/O circuitry configured to bias the first transistor of the first type with an I/O supply voltage; and
core circuitry configured to bias the first transistor of the second type with a core supply voltage lower than the I/O supply voltage.

7. The device of claim 1, comprising:
a third transistor of the first type including a third source/drain region in the first semiconductor fin;
a fourth transistor of the first type including a fourth source/drain region in the first semiconductor fin;
a second trench isolation region between the third source/drain region and the fourth source/drain region; and
a second dummy gate structure having a first edge on a third portion of the top surface of the first semiconductor fin and a second edge on the second trench isolation region; and
a third dummy gate structure having a first edge on a fourth portion of the top surface of the first semiconductor fin and a second edge on the second trench isolation region adjacent to the second edge of the second dummy gate structure.

8. The device of claim 1, wherein the first transistor of the first type includes a first lightly doped source/drain region, wherein the first dummy gate structure overlies the first lightly doped source/drain region.

9. The device of claim 8, wherein the second transistor of the first type includes second lightly doped source/drain region, wherein the first dummy gate structure overlies the second lightly doped source/drain region.

10. The device of claim 1, comprising a dummy gate contact electrically coupled to the first dummy gate structure and configured to apply a bias voltage to the first dummy gate structure.

11. The device of claim 1, wherein the first type of transistor is I/O transistor, wherein the second type of transistor is core transistor.

12. A method, comprising:
forming a first transistor including a first source/drain region in a first semiconductor fin and a first gate oxide on the first semiconductor fin, the first semiconductor fin extending in a first direction;
forming a second transistor including the first gate oxide and a second source/drain region in the first semiconductor fin separated from the first source/drain region by a first trench isolation region;
forming a first dummy gate structure overlying the first gate oxide and extending continuously across the first trench isolation region in the first direction;
forming a third transistor including a third source/drain region in a second semiconductor fin and a second gate oxide on the second semiconductor fin, the first gate oxide being thicker than the second gate oxide, the second semiconductor fin extending in the first direction;
forming a fourth transistor including the second gate oxide and a fourth source/drain region in the second semiconductor fin separated from the third source/drain region by a second trench isolation region; and
forming a second dummy gate structure overlying the second gate oxide and extending continuously across the second trench isolation dummy gate structure in the first direction.

13. The method of claim 12, comprising forming the second gate oxide after forming the first gate oxide.

14. The method of claim 13, comprising forming a high-K gate dielectric on both the first gate oxide and the second gate oxide.

15. The method of claim 12, comprising depositing a metal layer of a first gate structure of the first transistor, a metal layer of a second gate structure of the second transistor, and a metal layer of the first dummy gate structure in a same deposition process.

16. The method of claim 12, comprising:
forming a fifth transistor including a fifth source/drain region in the first semiconductor fin;
forming a sixth transistor including a sixth source/drain region in the first semiconductor fin;
forming a third trench isolation region between the fifth source/drain region and the sixth source/drain region; and
forming a third dummy gate structure having a first edge adjacent to the fifth source/drain region and a second edge on the third trench isolation region; and
forming a fourth dummy gate structure having a first edge adjacent to the sixth source/drain region and a second edge on the second trench isolation region adjacent to the second edge of the third dummy gate structure.

17. The method of claim 12, wherein forming the first dummy gate structure includes removing a sacrificial dummy gate structure and replacing the sacrificial dummy gate structure with the dummy gate structure.

18. A device, comprising:
I/O circuitry including:
a first transistor of a first type;
a second transistor of the first type; and
an I/O CPODE structure between the first transistor of the first type and the second transistor of the first type; and
core circuitry including:
a first transistor of a second type;
a second transistor of the second type; and
a core CPODE structure between the first transistor of the second type and the second transistor of the second type.

19. The device of claim 18, wherein the I/O circuitry includes an analog to digital converter including the first transistor of the first type and the second transistor of the first type.

20. The device of claim 18, wherein the I/O circuitry is configured to drive the first and second transistors of the first type with an I/O supply voltage, wherein the core circuitry is configured to drive the first and second transistors of the second type with a core supply voltage lower than the I/O supply voltage.
